(19) United States
(12) Patent Application Publication
(10) Pub. No.: US 2024/0178033 A1
(43) Pub. Date: May 30, 2024

(54) METHOD, SYSTEM AND APPARATUS FOR SUBSTRATE HANDLING AND COOLING

(71) Applicant: ASM IP Holding B.V., Almere (NL)

(72) Inventors: Jithin Prabha, Tempe, AZ (US); Joseph Kraus, Brandon, FL (US); Pawan Rao, Cupertino, CA (US)

(21) Appl. No.: 18/523,172

(22) Filed: Nov. 29, 2023

Related U.S. Application Data
(60) Provisional application No. 63/385,538, filed on Nov. 30, 2022.

(51) Int. Cl. H01L 21/677; H01L 21/67; H01L 21/687

(52) U.S. Cl. CPC H01L 21/67742; H01L 21/67109; H01L 21/68707

(57) ABSTRACT

A substrate cooling apparatus includes a cooling plate with a top surface including an array of embedded substrate support members protruding therefrom. A channel is disposed in an underside portion of the cooling plate, the conduit is embedded in the channel, a conduit comprising a coolant inlet at a first end and a coolant outlet at a second end, and a viscous thermally conductive material is disposed in the channel and is thermally coupled to an interior surface of the channel and an exterior surface of the conduit. One or more open recesses are disposed in a top surface of the cooling plate extending inward from a perimeter of the cooling plate toward a center point of the cooling plate, the open recesses disposed circumferentially on diametrically opposite sides of the cooling plate wherein the open recesses are sized to receive a corresponding substrate handling member of an indexer. Substrate transfer systems, cooling plate arrangements, and substrate transfer methods are also described.

### CROSS-REFERENCE TO RELATED APPLICATIONS

This application claims priority to and the benefit of U.S. Provisional Patent Application No. 63/385,538, filed Nov. 30, 2022, the contents of which are incorporated herein by reference in their entirety.

### FIELD OF THE DISCLOSURE

Examples of the present disclosure generally relate to substrate processing, and more particularly, for pre- and post-process handling and cooling during substrate processing. BACKGROUND OF THE DISCLOSURE

Semiconductor devices, such as transistors, diodes, and integrated circuits, are typically fabricated simultaneously on a thin wafer of semiconductor material, often referred to as a substrate, wafer, and/or workpiece. Processing methods include vacuum evaporation deposition, molecular beam epitaxy, variants of chemical vapor deposition (CVD) and atomic layer deposition (ALD). These methods generally involve forming a thin film, or layer, of a material by deposition on an exposed surface of the substrate.

In some semiconductor manufacturing processes, unprocessed substrates are transported from cassettes into a load lock chamber holding and/or pre-processing area. Substrates are then transported through a substrate handling chamber to a process module for processing. Once complete in one process module, the substrate may be transferred to a different processing module to continue processing. The transfer between different process modules may involve passing through the previous substrate handling area or passing through a different substrate handling area. Transfer between substrate handling areas and/or multiple process modules may include transfer through a passthrough chamber. Once processing is complete the substrate is typically moved back to the load lock for cooling, post-processing and transport (e.g., to packaging). In all such processes, it is generally desirable to maximize the speed at which substrates can be processed by semiconductor processing systems, also known as throughput. A bottleneck may occur where there is a process step that is slower than other process steps resulting in overall slowing of throughput.

Cooling of the substrate can cause a bottleneck because it is typically a time-consuming process. A cooling plate is often used to cool substrates after processing at very high temperatures while they are being transferred from processing modules to a post-processing area of the semiconductor manufacturing equipment (SME). Conventional substrate cooling plates include cutouts for lift pins at the center of the cooling plate. Such cutouts adversely affect the cooling uniformity of the substrate and delays cooling as there is reduced surface area to dissipate heat. Moreover, substrate warping can occur due to thermal stresses developed due to non-uniform cooling around cutouts. Additionally, conventional cooling plates have a coolant channel located between two bolted plates further increasing downtime to perform frequent repairs due to leaks between the plates. The cooling plates may be located in the load lock, the passthrough chamber between the two substrate handling chambers or other locations on SME. Processing tools often utilize computer implemented schedulers in an attempt to sequence the actions of the process tools (such as the transfer of substrates between different components of the tool) in the most efficient manner possible.

Such systems and methods have generally been acceptable for their intended. However, there remains a need for improved cooling apparatuses, cooling plate arrangements, substrate transfer system, and substrate transfer method. The present disclosure provides a solution to this need.

### SUMMARY OF THE DISCLOSURE

Disclosed herein are various methods, systems and apparatus for substrate handling and cooling. In an example, a cooling apparatus may include a cooling plate comprising a top surface having an array of embedded substrate support members protruding therefrom. The cooling plate may include a channel disposed in an underside portion of the cooling plate. The channel may include a conduit embedded in the channel comprising a coolant inlet at a first end and a coolant outlet at a second end. In an example, a viscous thermally conductive material may be disposed in the channel and thermally coupled to an interior surface of the channel and an exterior surface of the conduit. The cooling plate may further comprise one or more open recesses disposed in a top surface of the cooling plate extending inward from a perimeter of the cooling plate toward a center point of the cooling plate. The top surface may further include a segmented raised boundary disposed circumferentially about a perimeter of the cooling plate. The open recesses in the top surface may be disposed circumferentially on diametrically opposite sides of the cooling plate wherein the open recesses are sized to receive a corresponding substrate handling member of an indexer.

In addition to one or more of the features described above, or as an alternative, further examples may include that the array of embedded substrate support members comprise a plurality of standoff spheres each partially embedded in a corresponding cavity in the top surface of the cooling plate wherein the standoff spheres protrude above the top surface of the cooling plate by about 0.3 mm. In an example, standoff spheres may be held in place by a vented screw mated into a threaded hole adjacent to one of the standoff spheres. The standoff spheres may comprise silicon nitride, quartz or ceramic, or a combination thereof. Further examples include the cooling apparatus having an array of venting channels patterned into the top surface.

In addition to one or more of the features described above, or as an alternative, further examples include a cooling plate arrangement, comprising a cooling plate wherein the indexer further comprises an actuator assembly configured to translate along a vertical axis to a first position and a second position. A crossbeam may be cantilevered and extend from the actuator assembly along a horizontal axis with respect to the actuator assembly, wherein the indexer is radially offset from the cooling plate. The cooling plate arrangement may further comprise a plurality of substrate handling members coupled to the crossbeam, arranged in pairs at opposing ends of the crossbeam. In an example, a first set of opposing pairs of substrate handling members may be positioned to circumferentially support a first substrate. A second set of opposing pairs of substrate handling members may be disposed to circumferentially support a second substrate, wherein the first set is disposed lower than the second set. Corresponding ones of the substrate handling members of the first set may be sized to engage with respective ones of the one or more open recesses. In further examples, a pair of spacer block assemblies may be coupled to an underside of the crossbeam at opposing ends. Individuals of the pair of spacer block assemblies may further comprise at least a first pair of slots and a second pair of slots disposed vertically above the first pair of slots. Individuals of the pair of spacer block assemblies may further comprise a first pair of substrate handling members each having a first mating end engaged within respective ones of the first pair of slots and a second pair of substrate handling members each having a second mating end engaged within respective ones of the second pair of slots.

In addition to one or more of the features described above, or as an alternative, further examples include a cooling plate arrangement, wherein individual ones of the plurality of substrate handling members comprise a transport end having an end face directed toward a transverse plane through a center of the crossbeam, the end face comprising a recessed edge including an angled sidewall that is spaced apart from the end face. In some examples, the angled sidewall or the end face, or a combination thereof, may be disposed at acute interior angles or obtuse interior angles with respect to a centerline parallel to a lengthwise axis of the substrate handling member.

An example substrate transfer system is disclosed herein including a cooling plate arrangement as recited above and a substrate transfer chamber including a housing to enclose the cooling plate and the indexer, wherein the indexer comprises a lower substrate transfer arrangement including the first opposing vertical pair and an upper substrate transfer arrangement including the second opposing vertical pair. A controller may be disposed in communication with and operatively connected to the indexer, the controller responsive to instructions recorded on a non-transitory machine-readable memory is to lower the indexer to the first position to mate the first opposing vertical pair within the open recesses or to raise the indexer to the second position removing the first opposing pair from within the open recesses, or a combination thereof.

In addition to one or more of the features described above, or as an alternative, further examples include the cooling plate arrangement, wherein the controller is further in communication and operatively connected with a first gate valve coupled to the housing and a second gate valve coupled to the housing and wherein the instructions further cause the controller to simultaneously close the first gate valve and raise the indexer to the second position.

In addition to one or more of the features described above, or as an alternative, further examples include the cooling plate arrangement, wherein the instructions further cause the controller to simultaneously open the first gate valve and close the second gate valve.

In addition to one or more of the features described above, or as an alternative, further examples include the cooling plate arrangement, wherein the controller is further in communication and operatively connected with a first gate valve coupled to the housing, a second gate valve coupled to the housing, a first transfer arm disposed adjacent to the first gate valve and a second transfer arm disposed adjacent to the second gate valve and wherein the instructions further cause the controller to:
a) move the indexer to the first position;
b) open the first gate valve;
c) extend the first transfer arm to insert an unprocessed substrate through the open first gate valve and position the unprocessed substrate on an upper substrate transfer arrangement;
d) move the indexer to a second position;
e) close the first gate valve;
f) open the second gate valve;
g) extend the second transfer arm to insert a processed substrate through the open second gate valve and position the processed substrate on the lower substrate transfer arrangement;
h) move the indexer to the first position;
i) extend the second transfer arm through the open second gate valve to remove the unprocessed substrate from the upper substrate transfer arrangement;
j) close the second gate valve;
k) open first gate valve;
l) extend the first substrate transfer arm through the open first gate valve to insert a second unprocessed substrate through the open first gate valve and position the second unprocessed substrate on the upper substrate transfer arrangement;
m) move indexer to the second position; and
n) remove the processed substrate from the lower substrate transfer arrangement through open first gate valve.

In some examples, the instructions may further cause the controller to perform actions a-n sequentially. The instructions may also cause the controller to proceed from action e upon completing action n. Further, the instructions may cause the controller to perform actions d-e-f or j-k simultaneously, or a combination thereof.

A substrate transfer method is disclosed. In an example, the method includes, at a chamber arrangement including a transfer chamber opening to a first gate valve and a second gate valve, a cooling plate comprising a top surface having one or more open recesses extending inward from a perimeter of the cooling plate toward a center point of the cooling plate, an indexer radially offset from the cooling plate comprising an actuator assembly configured to translate along a vertical axis to a first position and a second position, and a crossbeam cantilevered and extending from the actuator assembly along a horizontal axis with respect to the actuator assembly, and a plurality of substrate handling members coupled to the crossbeam,
a) moving the indexer to a first position and coupling the plurality of substrate handling members into corresponding open recesses;
b) opening the first gate valve;
c) inserting an unprocessed substrate through the open first gate valve and positioning the unprocessed substrate on an upper substrate transfer arrangement;
d) moving the indexer to a second position;
e) closing the first gate valve;
f) opening the second gate valve;
g) inserting a processed substrate through the open second gate valve and positioning the processed substrate on the lower substrate transfer arrangement;
h) moving the indexer to the first position and coupling the one or more substrate handling members into the corresponding open recesses to cool the processed substrate;
i) removing the unprocessed substrate from the upper substrate transfer arrangement through the open second gate valve;
j) closing the second gate valve;
k) opening first gate valve;
l) inserting a second unprocessed substrate through the open first gate valve and positioning the second unprocessed substrate on the upper substrate transfer arrangement;
m) moving indexer to the second position; and
n) removing the cooled processed substrate from the lower substrate transfer arrangement through open first gate valve.

In some examples the substrate transfer method may further comprise performing actions a-n sequentially. The substrate transfer method may further comprise proceeding to action e upon completing action n. Further, the substrate transfer method may further comprise proceeding to perform actions d-e-f or j-k simultaneously, or a combination thereof.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a diagram illustrating a plan view of an example substrate processing apparatus.

FIG. 2A is a diagram illustrating an exploded view of an example load lock.

FIG. 2B is a diagram illustrating a perspective view of the example load lock illustrated in FIG. 2A.

FIG. 3A is a diagram illustrating perspective and detailed views of an example cooling plate.

FIG. 3B is a diagram illustrating a cutaway perspective view of the example cooling plate illustrated in FIG. 3A.

FIG. 3C is a diagram illustrating a cutaway view of the example cooling plate shown in FIGS. 3A-3B.

FIG. 3D is a diagram illustrating an underside perspective view of the example cooling plate shown in FIGS. 3A-3C.

FIG. 4A is a diagram illustrating a perspective view of the example adapter shown in FIG. 2A.

FIG. 4B is a diagram illustrating a perspective view of an example assembly of the adapter and cooling plate shown in FIGS. 2A.

FIG. 4C is a diagram illustrating a perspective view of an example assembly of the adapter, cooling plate, and indexer shown in FIG. 2A.

FIG. 4D is a diagram illustrating a perspective view of the example adapter, crossbeam, and cooling plate shown in FIGS. 4A-4C assembled within an example load lock chamber.

FIG. 5A is a diagram illustrating a perspective view of an example indexer.

FIG. 5B is a diagram illustrating a side view of the example indexer shown in FIG. 5A.

FIG. 5C is a diagram illustrating a perspective view of an example crossbeam shown in FIGS. 5A-5B.

FIG. 5D is a diagram illustrating a perspective view of an example substrate handling member shown in FIGS. 5A-5C.

FIG. 5E is a diagram illustrating a perspective view of example substrate handling members shown in FIGS. 5A-5D.

FIG. 6A is a diagram illustrating an example substrate transfer system and controller.

FIG. 6B is a diagram illustrating the example substrate transfer system and controller shown in FIG. 6A.

FIG. 6C is a diagram illustrating an example indexer.

FIG. 6D is a diagram illustrating an example schedule for a substrate transfer process.

FIG. 6E is a diagram illustrating an example substrate transfer system between substrate processing assemblies.

FIG. 6F is a diagram illustrating an example substrate transfer system for storage and cooling within a substrate processing assembly.

FIG. 7 is a flowchart illustrating an example method of scheduling substrate transfer.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationships or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

As used herein, the term “substrate” may refer to any underlying material or materials that may be used, or upon which, a device, a circuit, or a film may be formed. The “substrate” may be continuous or non-continuous, rigid, flexible, solid or porous. Substrates in the form of a plate may include wafers, e.g., 300-millimeter silicon wafers, in various shapes and sizes. Substrates may be made from materials such as silicon, silicon germanium, silicon oxide, gallium arsenide, gallium nitride and silicon carbide by way of non-limiting example. A continuous substrate may extend beyond the bounds of a process chamber where a deposition process occurs and may move through the process chamber such that the process continues until the end of the substrate is reached. A continuous substrate may be supplied from a continuous substrate feeding system, enabling manufacture and output of the continuous substrate in any appropriate form.

To at least address the above noted deficiencies of the conventional methods of handling and cooling substrates before, during and after processing, disclosed herein are methods, systems and apparatus to reduce cooling time by removing apertures or holes through which lift pins extend from the center of a cooling plate to enable higher substrate cooling uniformity. In addition, use of thermally resistant standoffs between the cooling plate and substrate are proposed to support the substrate during cooling to further promote cooling uniformity. A conduit embedded within the cooling plate cooling channel is disclosed to prevent coolant leakage reducing downtime further. Also disclosed is a method of scheduling handling a plurality of substrates during cooling to leverage cooling time and improve throughput.

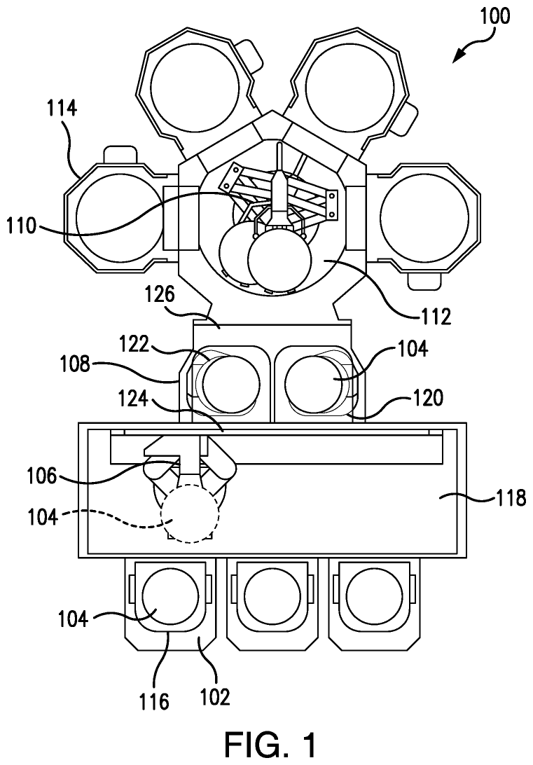

FIG. 1 is a schematic illustrating an example of a substrate processing assembly 100. Substrate processing assembly 100 may be configured to process or test a substrate by leveraging a variety of chemistries, atmospheric conditions and/or environmental conditions according to selected processing recipes or testing routines. The following description of an example substrate processing assembly 100 is simplified for illustrative purposes and is not intended to be limiting.

In an example, substrate processing assembly 100 comprises a load port 102 coupled to a front-end transfer module 118. In some examples, a plurality of load ports may be coupled to front-end transfer module 118 that operate similarly to load port 102.

In an example, load port 102 is configured to receive a cassette 116. Cassette 116 comprises a housing to enclose at least one substrate 104 in a controlled environment to maintain a clean atmosphere and avoid contamination during processing of substrate 104.

Front-end transfer module 118 houses a front-end transfer apparatus 106 configured to transport substrate 104 from cassette 116 through front-end transfer module 118 to a passthrough chamber, for example, load lock assembly 108. Load lock assembly 108 may comprise a plurality of chambers such as chamber 120 and/or chamber 122. In an example, substrate 104 may be received within chamber 120 or chamber 122 via an integrated portal (not shown). Front-end transfer module 118 may be arranged to allow passage between front-end transfer module 118 and load lock assembly 108 in a controlled environment. For example, front-end transfer module 118 may enclose an ultra-clean environment at a variety of pressures to minimize contamination of substrate 104 before and after processing.

In an example, front-end transfer apparatus 106 may be a robotic arm operable to rotate and move in multiple axes so as to transfer substrate 104 from cassette 116 to load lock assembly 108. Similarly, back-end transfer apparatus 110 may be a robotic arm operable to rotate and move in multiple axes so as to transfer substrate 104 from load lock assembly 108 to substrate handling chamber 112 and/or to a reaction chamber, such as reaction chamber 114, where substrate 104 may be processed. Substrate handling chamber 112 may be coupled to a plurality of reaction chambers 114 configured for any of a variety of fabrication processes known to those of skill in the art. Substrate 104 may undergo one or more processing steps in one or more reaction chambers 114 before processing is complete.

Back-end transfer apparatus 110 may remove substrate 104 from a reaction chamber, such as reaction chamber 114, and transport it back to load lock assembly 108. Substrate 104 may be received in either of chambers 120 and 122 to be cooled prior to removal by front-end transport apparatus 106 for disposition back in cassette 116 or to a different destination.

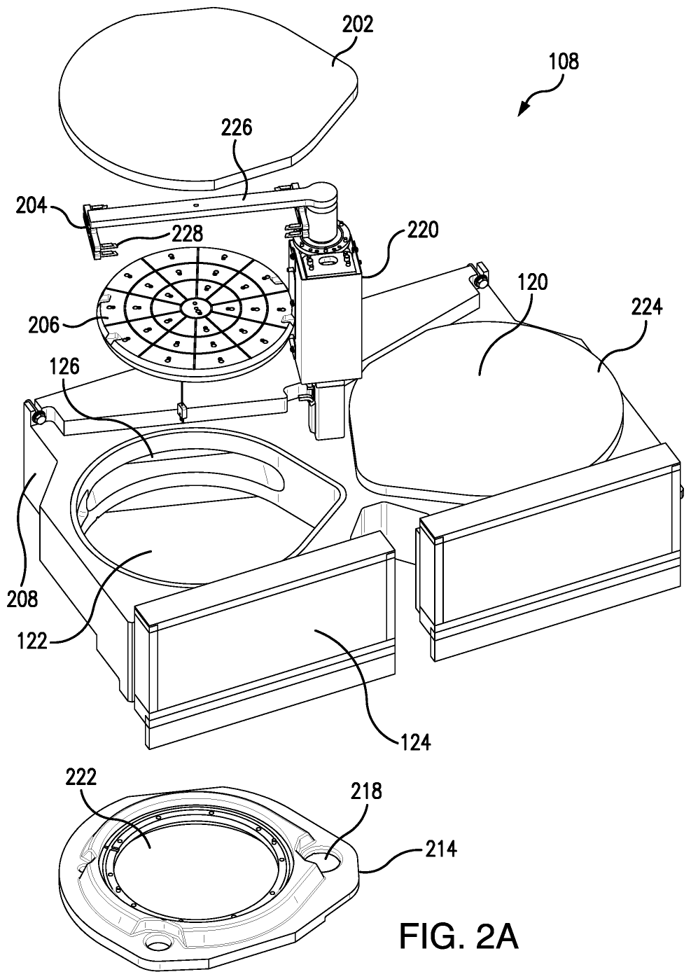

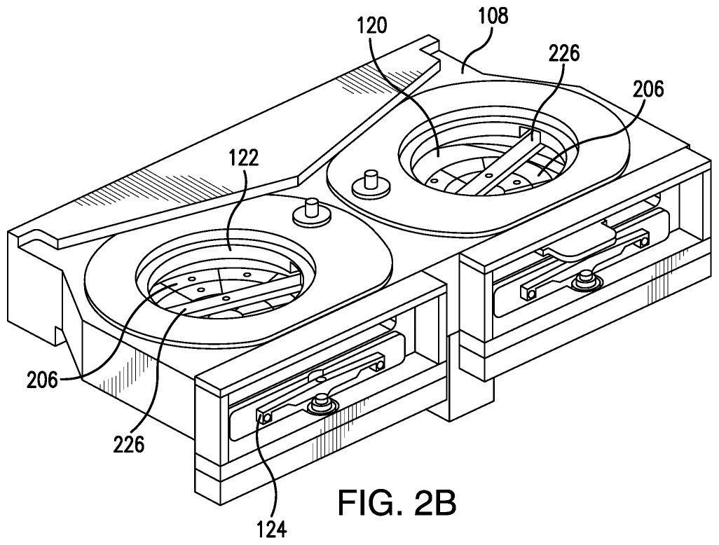

FIG. 2A is an exploded schematic illustrating an example of load lock assembly 108 (see FIG. 1) configured to pre- or post-process substrate 104 (see FIG. 1). Load lock assembly 108 comprises chamber 120 and chamber 122. For simplicity, chamber 122 and attendant exploded components will be described herein. However, chamber 120 may comprise the same or similar components as illustrated in FIG. 2A.

In an example, load lock assembly 108 includes one or more load lock lids 202 and 224, load lock housing 208, and a cooling plate 206. An indexer 204 is configured to hold a vertical stack of substrates and is disposed above cooling plate 206. Indexer 204 comprises an actuator 220 coupled to a cantilevered crossbeam 226 having a plurality of circumferentially disposed substrate handling members 228 configured to stack and space apart the vertical stack of substrates. Load lock assembly 108 also includes a front-end gate valve 124 and a back-end gate valve 126 through which one or more substrates 104 may be transferred.

In an example, an adapter plate 214 is configured to mount indexer 204 and/or cooling plate 206 within load lock chamber 122. Second aperture 218 of adapter plate 214 is configured to receive and support actuator 220 of indexer 204. First aperture 222 of adapter plate 214 is configured to receive and/or support cooling plate 206. As assembled, cooling plate 206, indexer 204 and adapter plate 214 are contained within load lock chamber 122. Housing 208 envelops chamber 122 providing an environment for cooling, processing and/or storage.

FIG. 2B is a diagram illustrating an example of load lock assembly 108 (see FIG. 1) with lids 202 and 224 (see FIG. 2A) removed. The assembly of cooling plate 206 and crossbeam 226 of indexer 204 are visible within chambers 120 and 122.

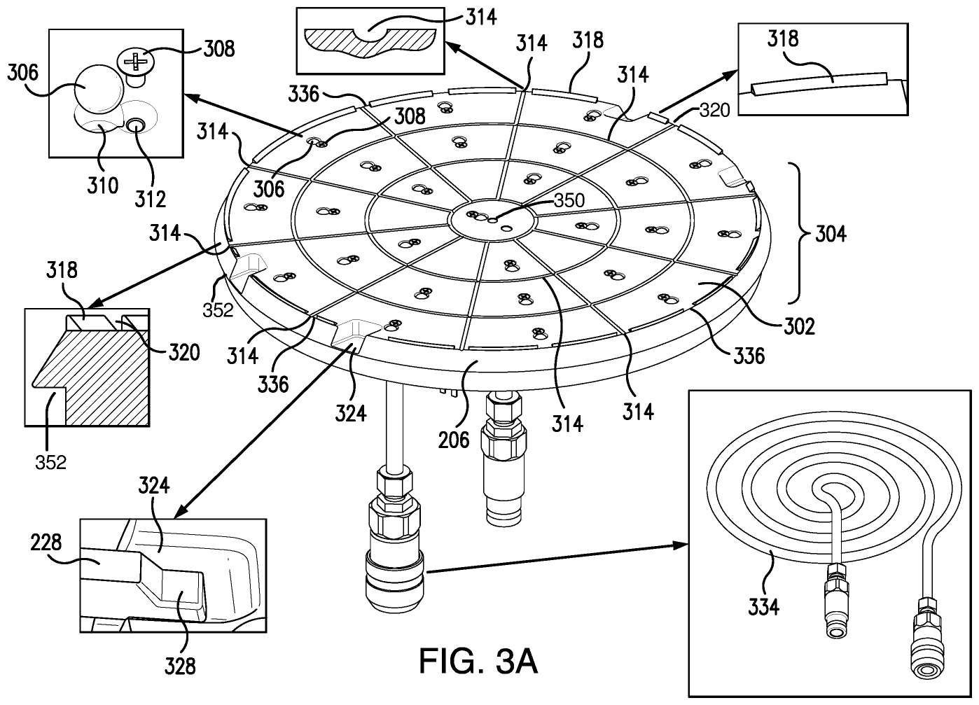

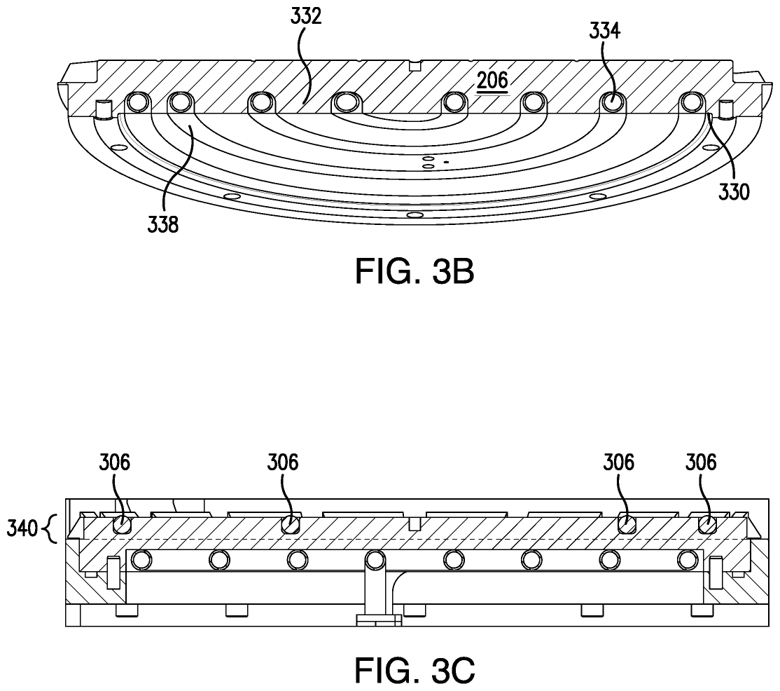

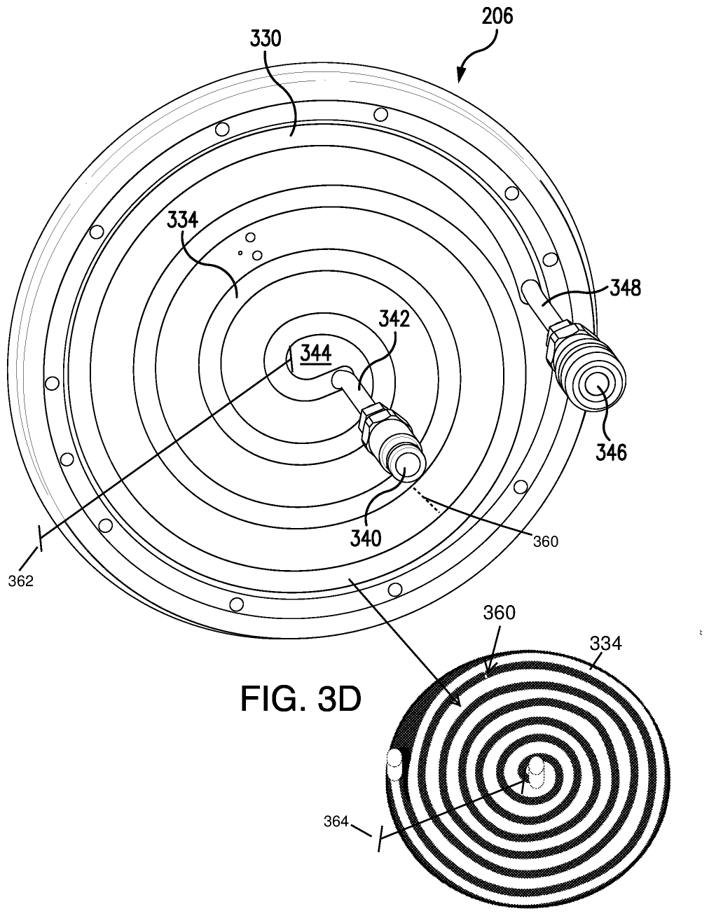

FIG. 3A-3D are diagrams illustrating various features of example cooling plate 206. Referring now to FIG. 3A, cooling plate 206 is configured to dissipate heat away from substrate 104 after exposure to extreme heat (e.g., between about 200°-1500° C.) during processing. In an example, cooling plate 206 is configured to provide structural support to a substrate 104 to promote uniform heat dissipation and/or to minimize deformation of the substrate 104. Such support may be provided by an array 304 of embedded substrate support members such as standoff spheres 306. Standoff spheres 306 may each be partially embedded in a cavity 310 in upper portion 326 of substrate cooling plate 206. Cavity 310 may open to top surface 302. Standoff spheres 306 may protrude above top surface 302. In an example, a portion of one or more of the standoff spheres 306 may protrude above top surface 302 by between about 0.1 millimeters and about 10.0 millimeters, or between about 0.2 millimeters and about 0.7 millimeters, or between about 0.2 millimeters and about 0.5 millimeters, or about 0.3 millimeters. Standoff spheres 306 may receive and support substrate 104 (see FIG. 1) spaced apart from top surface 302 providing a gap 316 (see FIG. 3D) having a width about equal to the distance the standoff spheres 306 protrude above top surface 302. In an example, gap 316 may be sufficient to reduce the risk of damage or contamination to substrate 104 yet in close enough proximity to promote thermal transfer between the substrate 104 and cooling plate 206.

As described, array 304 of embedded substrate support members is configured to support and separate a lower surface of substrate 104 from top surface 302 to reduce the risk of contamination or damage to substrate 104 while limiting the gap size enabling better convective and/or radiative heat transfer between cooling plate 206 and substrate 104. In some examples, a layout of array 304 may be selected to position standoff spheres 306 a predetermined maximum distance apart in the horizontal plane across top surface 302 to reduce deformation of substrate 104 during cooling which may promote more uniform cooling of substrate 104. For example, two standoff spheres may be separated horizontally by no more than between about 10.0 millimeters and about 150.0 millimeters, or between about 20.0 millimeters and about 120.0 millimeters, or between about 30.0 millimeters and about 100.0 millimeters, or about 80.0 millimeters. More uniform cooling may further reduce the risk of deformation of substrate 104 during cooling. By minimizing deformation, substrate 104 is less likely to come into contact with cooling plate 206 thus reducing the risk of contamination and/or damage that may be caused by coming into contact with cooling plate 206. Standoff spheres 306 may comprise any of a variety of materials such as but not limited to heat resistant materials including, for example, silicon nitride (Si₃N₄), aluminum nitride (AlN), quartz (SiO₂), alumina (Al₂O₃), zirconia (ZrO₂), silicon carbide (SiC), Sialon, ceramic, or the like or a combination thereof.

In an example, at least one of standoff spheres 306 may be held in place by a corresponding vented screw 308. Vented screw 308 may be mated into a threaded hole 312 adjacent to the at least one of the standoff spheres 306 to securely fasten it within cavity 310. Vented screw 308 may allow gas to escape from cavity 310 to prevent gas buildup around standoff sphere 306 during cooling of substrate 104. This may prevent damage or destabilization of standoff spheres 306 and/or substrate 104 during the large temperature fluctuations that can occur during cooling.

In an example, top surface 302 includes recessed venting channels 314 configured to direct gas away from substrate 104 disposed on cooling plate 206. Venting channels 314 may be fabricated in a pattern over top surface 302 of cooling plate 206. Such patterning may comprise a web or grid as non-limiting examples.

In an example, cooling plate 206 may include a raised boundary 318 on top surface 302. Raised boundary 318 may be disposed about a perimeter 336 of a circumference of top surface 302 to prevent substrate 104 misalignment with cooling plate 206, for example, during processing, testing, transit and/or storage. Raised boundary 318 may be contiguous or may comprise a plurality of segments separated by one or more spaces 320.

In an example, one or more open recesses 324 may be disposed in top surface 302 of cooling plate 206. Open recesses 324 may extend inward from perimeter 336 of cooling plate 206 toward a center point 350. In an example, open recesses 324 are disposed circumferentially on diametrically opposite sides of the cooling plate 206. One or more open recesses 324 are sized to receive a corresponding substrate handling member 228 of indexer 204 (see FIG. 2A).

In an example, substrate handling member 228 may be fabricated from ceramic, quartz, or other thermally tolerant material, or a combination thereof. Substrate handling member 228 may be configured to contact substrate 104 (see, FIG. 1). It may include an angled sidewall 328 configured to serve as a substrate guide to circumferentially align and/or secure substrate 104 in a transfer plane of indexer 204. Such aligning and/or securing may occur, for example, during transfer into and out of load lock assembly 108 and/or during vertical translation of indexer 204 within load lock assembly 108 (see FIG. 2A).

In an example, flared perimeter 352 is disposed circumferentially about perimeter 336 of cooling plate 206. Flared perimeter 352 may prevent particles (such as from substrate 104) from entering or falling into areas of load lock assembly 108 where they may cause damage.

As described in greater detail below, cooling plate 206 may include cooling conduit 334 embedded in cooling channels on an underside of cooling plate 206.

In an example, cooling plate 206 may be fabricated from a high thermal conductivity metal such as aluminum (Al) or other thermally conductive metals or metal alloy. In certain examples, cooling plate 206 may not comprise copper (Cu) and/or iron (Fe) to prevent contamination of substrate 104 (see FIG. 2A). Cooling plate 206 may be fabricated by 3D printing, molding, machining, etching, or other methods know to those of skill in the art.

Referring now to FIGS. 3B-3C, cooling plate 206 may comprise cooling channel 330 embedded in underside portion 332 of cooling plate 206. Cooling channel 330 may open to underside surface 344 of cooling plate 206 and may be sized and configured to receive conduit 334. Conduit 334 may be encased within cooling channel 330 and secured therein using a viscous thermally conductive material 338. In an example, viscous thermally conductive material 338 may be disposed in cooling channel 330 and thermally coupled to an interior surface 354 of cooling channel 330 and an exterior surface 356 of conduit 334. Thus, conduit 334 may conduct and/or dissipate heat between cooling plate 206 and a coolant flowing in conduit 334. In an example, viscous thermally conductive material 338 may be a thermal epoxy, resin, thermally conductive silicone or polymer, or the like or combinations thereof.

FIG. 3D illustrates a perspective view of an underside surface 344 of an example cooling plate 206. A spiral pitch 360 (gap between adjacent turns of a spiral) of cooling channel 330 may vary. For example, pitch 360 may comprise a loose spiral 362 or alternatively a tighter spiral 364 wherein adjacent turns of spiral 364 are abutting one another.

In an example, cooling plate 206 may not have apertures or holes to admit lift pins therethrough. Thus, the arrangement of cooling channel 330 and cooling conduit 334 across underside 344 may be uninterrupted promoting more even cooling of substrate 104 (see FIG. 1). In an example, a coolant inlet 340 at a first end 342 of conduit 334 and a coolant outlet 346 at a second end 348 are configured to allow a coolant to flow through conduit 334 to dissipate heat from cooling plate 206. In other examples, coolant outlet 346 may be disposed at first end 342 of conduit 334 and coolant inlet 340 may be disposed at second end 348 of conduit 334 and claimed subject matter is not limited in this regard.

Cooling conduit 334 may comprise any of a variety of thermally conductive materials. An example material is stainless steel (SS or SUS) which may be used to prevent galvanic corrosion that may be caused by use of water as a coolant. Other coolants may be used such as, but not limited to deionized water, glycol/water solutions, and dielectric fluid, or a combination thereof.

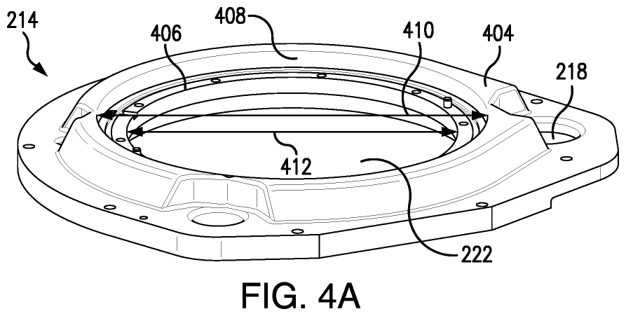

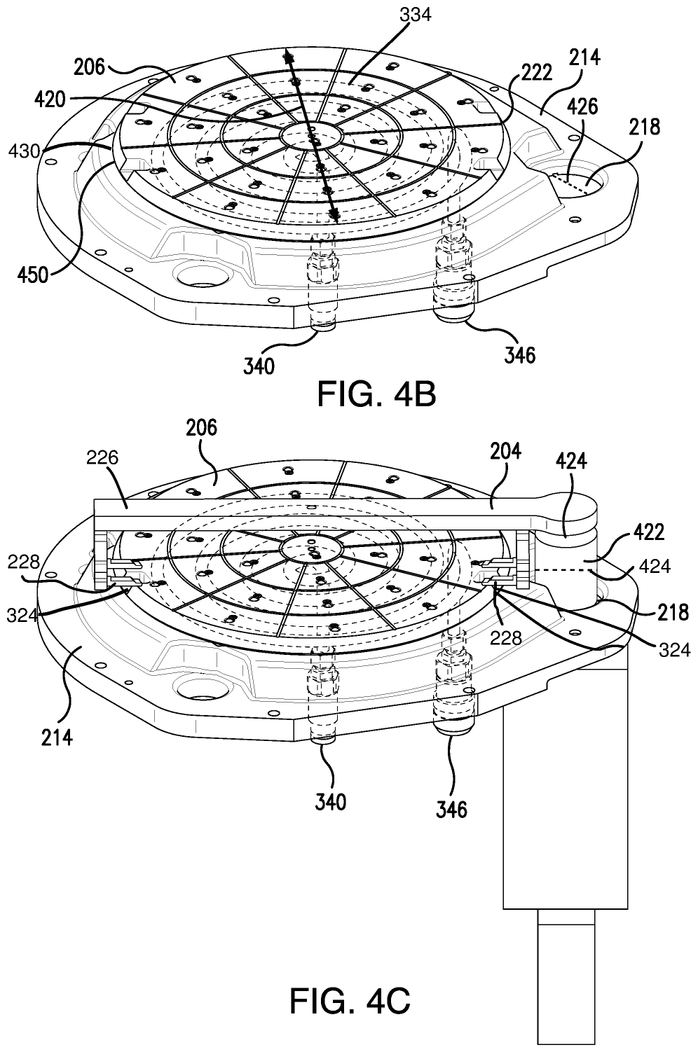

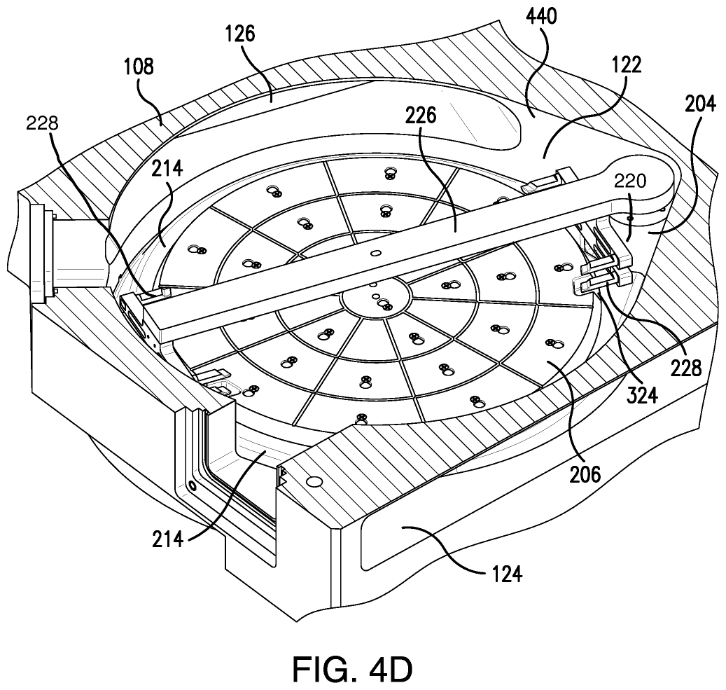

FIGS. 4A-4D are diagrams illustrating various views of example adapter plate 214 (shown in FIG. 2A) and assemblies thereof.

Referring to FIG. 4A, an example adapter plate 214 is illustrated in perspective view. In an example, adapter plate 214 may comprise a raised annular boss 404 defining a first aperture 222. Adapter plate 214 may further comprise an annular support member 406 configured to support cooling plate 206. Annular support member 406 may be disposed on an interior wall 408 of raised annular boss 404.

In an example, annular support member 406 may have a first inner diameter 410 that is greater than an outer diameter 420 of cooling plate 206 (see FIG. 4B) and greater than a second inner diameter 412 which is less than outer diameter 420 of cooling plate 206. Thus, annular support member 406 may provide a steplike support for cooling plate 206 to rest on when disposed within first aperture 222 of adapter plate 214. First inner diameter 410 and second inner diameter 412 may be aligned and/or coaxial.

FIG. 4B illustrates an example assembly of adapter plate 214 and cooling plate 206 in perspective view. Cooling plate 206 may be positioned within first aperture 222 such that a portion of cooling plate 206 extends above a rim 430 of adapter plate 214. Coolant inlet 340 and coolant outlet 346 coupled to conduit 334 (shown with hidden lines) extend into and/or through first aperture 222 for accessibility to coolant sources or coolant return.

FIG. 4C is a diagram illustrating a perspective view of an example assembly of adapter plate 214, cooling plate 206, and indexer 204 shown in FIG. 2A. In an example, adapter plate 214 may include a second aperture 218 having an inner diameter 426 (see FIG. 4B) that may be configured to receive indexer 204. Inner diameter 426 may be greater than an outer diameter 424 of vertical support member 422 of indexer 204. Vertical support member 422 may comprise a column, tube, bellow or the like or any combination thereof and may have a variety of shapes including circular, polygonal or the like or a combination thereof. Second aperture 218 may have a shape substantially matching the shape of vertical support member 422 and may have an inner perimeter configured to fit around an outer surface of vertical support member 422. In an example, vertical support member 422 may be slidably engaged with second aperture 218 so as to enable vertical translation of crossbeam 226 over cooling plate 206. Indexer 204 may be radially offset from the cooling plate 206. Adapter plate 214 may be operable to align cooling plate 206 and/or indexer 204 within load lock assembly 108 (see FIG. 2B) or other substrate transfer chamber. Second aperture 218 may be disposed adjacent to or inline with recesses 324 which may encourage positioning of substrate handling members 228 within recesses 324 during processing.

Referring to FIG. 4D, an example assembly of adapter plate 214, indexer 204 and cooling plate 206 (shown in FIGS. 4A-4C) as assembled within load lock assembly 108 are shown in perspective view. In an example, load lock assembly 108 includes cooling plate 206, indexer 204 including a crossbeam 226. Crossbeam 226 extends over cooling plate 206 and is cantileverly supported (e.g., cantilevered therefrom) by actuator 220. One or more substrate handling members 228 may be disposed within corresponding open recesses 324 of cooling plate 206. Substrate handling members 228 are circumferentially positioned to receive and hold at least two vertically stacked substrates (not shown). Load lock chamber 122 includes a housing 208 to enclose adapter plate 214, cooling plate 206, indexer 204 and any substrate being held, transferred, cooled, processed or stored within load lock chamber 122 or other substrate transfer chamber.

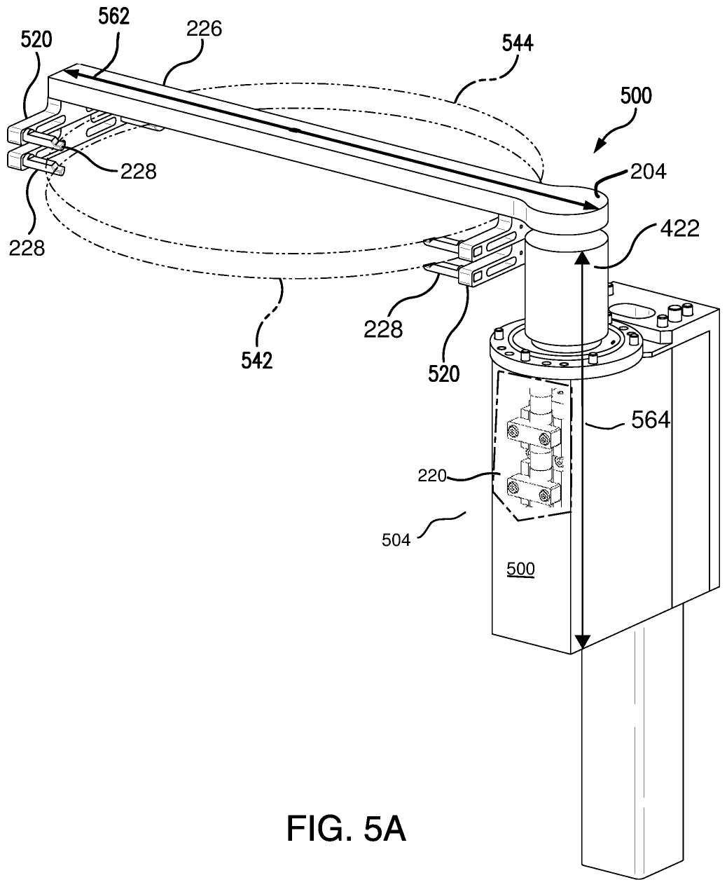

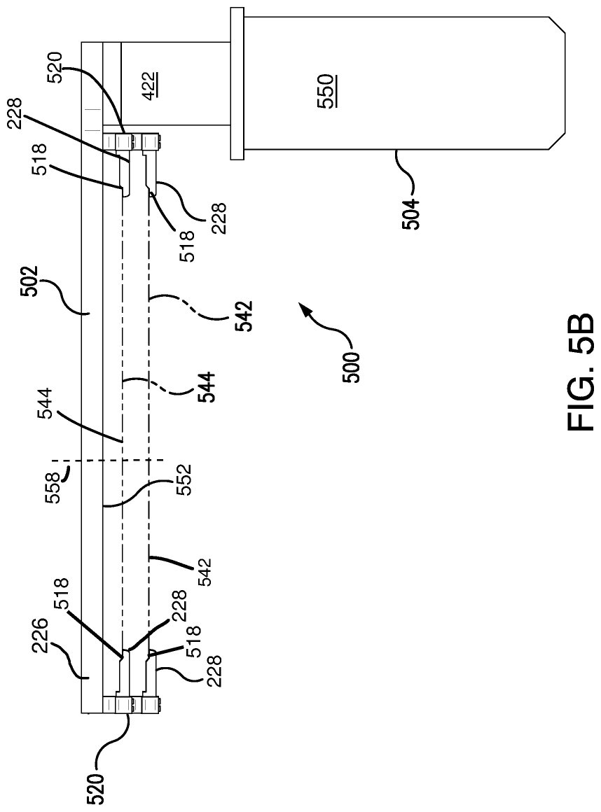

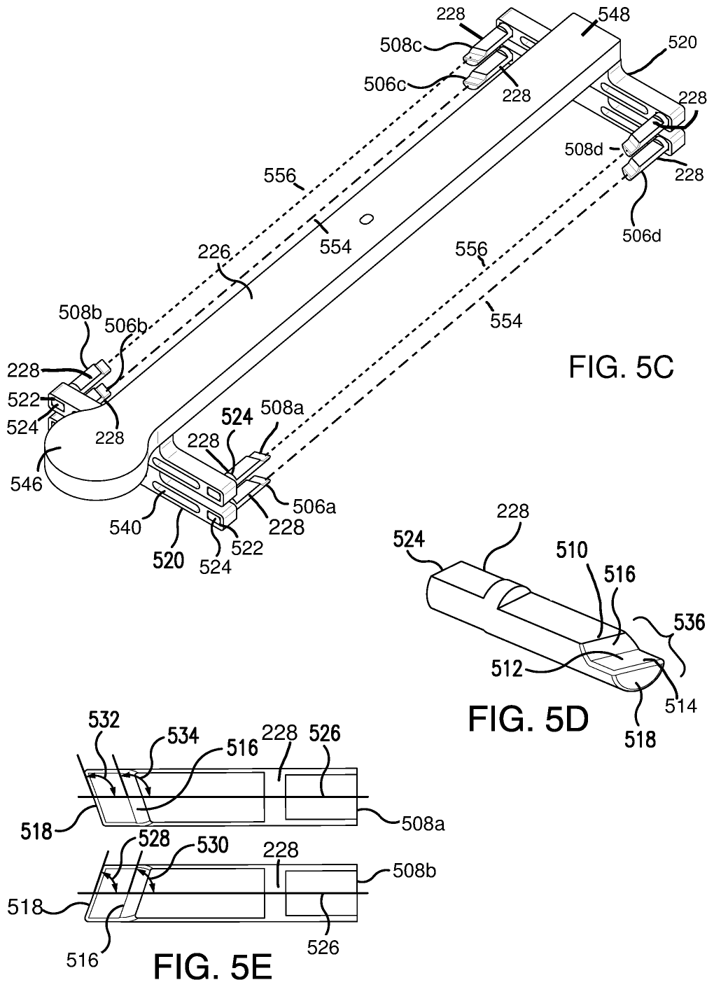

FIGS. 5A-5C are schematic diagrams illustrating various views of example indexer assembly 500. Referring to FIG. 5A, indexer assembly 500 is shown in perspective view. In an example, indexer assembly 500 may comprise indexer 204 and actuator assembly 504. Indexer 204 may comprise crossbeam 226, spacer blocks 520 and substrate handling members 228. Actuator assembly 504 may comprise actuator 220, vertical support member 422, and housing 550 enclosing actuator 220.

In an example, actuator assembly 504 may be configured to translate crossbeam 226 in a vertical axis 564 to at least a first position and a second position. In some examples, the first position may be lower in vertical axis 564 than the second position. A crossbeam 226 may be cantilevered and extend from vertical support member 422 along horizontal axis 562 with respect to actuator assembly 504. Actuator assembly 504 may include any of a variety of motors known to those of skill in the art to effectuate linear motion in vertical axis 564 including, but not limited to, a stepper motor, a servo motor, a linear motor, a pneumatic cylinder actuated assembly, or other conventional mechanical linear actuation devices.

FIG. 5B is a diagram illustrating a side cutaway view of the example indexer assembly 500 shown in FIG. 5A. In an example, one or more substrate handling members 228 are coupled to crossbeam 226 via a spacer block 520. Individual ones of substrate handling members 228 comprise a mating end 524 (see FIG. 5D) configured to engage with slots in corresponding spacer blocks 520 and an end face 518 directed toward a transverse plane 558 through a center of crossbeam 226. One or more spacer blocks 520 may extend vertically from underside 552 of crossbeam 226. Spacer blocks 520 may be integral with crossbeam 226 or may be coupled to crossbeam 226 via one or more fasteners, or by welding, brazing, or soldering, or the like or a combination thereof. In an example, substrate handling members 228 may be made of a variety of materials such as a thermally insulating material including but not limited to silicon nitride (Si₃N₄), aluminum nitride (AlN), quartz (SiO₂), alumina (Al₂O₃), zirconia (ZrO₂), silicon carbide (SiC), Sialon, ceramic, or the like or a combination thereof.

Referring now to FIG. 5C, example crossbeam 226 shown in FIGS. 5A-5B is illustrated in perspective view. In an example, individual spacer blocks 520 may comprise at least one slot 522 sized to engage a mating end 524 of corresponding ones of substrate handling members 228. Spacer blocks 520 may include additional apertures such as aperture 540, for example, to reduce the weight of spacer block 520.

In an example, indexer assembly 500 may include two or more spacer blocks 520 positioned opposite one another proximate to lengthwise end portions 546 and 548 of the crossbeam 226. Spacer blocks 520 may be configured to vertically stack a lower-level substrate 542 (see FIG. 5B) and an upper-level substrate 544.

In an example, during transport or storage by indexer assembly 500 (see FIG. 5B), diametrically opposed pairs of substrate handling members 228 may provide circumferential support to substrates positioned on end portions of paired substrate handling members 228 (herein the term “diametrically opposed” refers to being positioned approximately opposite one another on opposite ends of a diameter of a substrate). For example, substrate handling members 228 may be arranged in pairs, such as, first pair 506a, 506b, second pair 506c, 506d, third pair 508a, 508b and fourth pair 508c, 508d. Pairs of substrate handling members 228 may be mirror images of one another as discussed in more detail in FIG. 5E.

In an example, a first set of pairs 554 (indicated with dashed lines) may comprise first pair 506a, 506b disposed at a first end 546 of crossbeam 226 and second pair 506c, 506d disposed at the opposing second end 548 of crossbeam 226. Likewise, a second set of pairs 556 (indicated with dotted lines) may comprise third pair 508a, 508b disposed at first end 546 of crossbeam 226 and fourth pair 508c, 508d disposed at the opposing second end 548 of crossbeam 226.

In an example, first set of pairs 554 is positioned to circumferentially support lower-level substrate 542 (see FIG. 5B) and second set of pairs 556 is disposed to circumferentially support upper-level substrate 544 (see FIG. 5B). In some examples, first set of opposing pairs 554 is disposed lower than second set of opposing pairs 556.

FIG. 5D is a schematic illustrating an example substrate handling member 228 in perspective view. In an example, a substrate handling member 228 may include a transport end 510 configured to support a substrate positioned thereon. Transport end 510 may comprise an edge recess 512 disposed on a top surface 514 of substrate handling member 228. Edge recess 512 may include a substrate guide 536 comprising an angled sidewall 516 disposed proximate an end face 518 of substrate handling member 228.

Referring to FIG. 5E, showing example substrate handling member pair 508a, 508b in plan view. In an example, substrate handling members of third pair 508a, 508b may be mirror images of one another. Angled sidewall 516 may be disposed at an acute interior angle 530 or obtuse interior angle 534 with respect to centerline 526. End face 518 may be disposed at an acute interior angle 528 or an obtuse interior angle 532 with respect to centerline 526. In an example, acute interior angles 528, 530 may be the same or different. Likewise, obtuse interior angles 532, 534 may be the same or different. Angled sidewalls 516 and end faces 518 may be angled to conform to the circumference of lower-level substrate 542 or upper-level substrate 544 (see FIG. 5A).

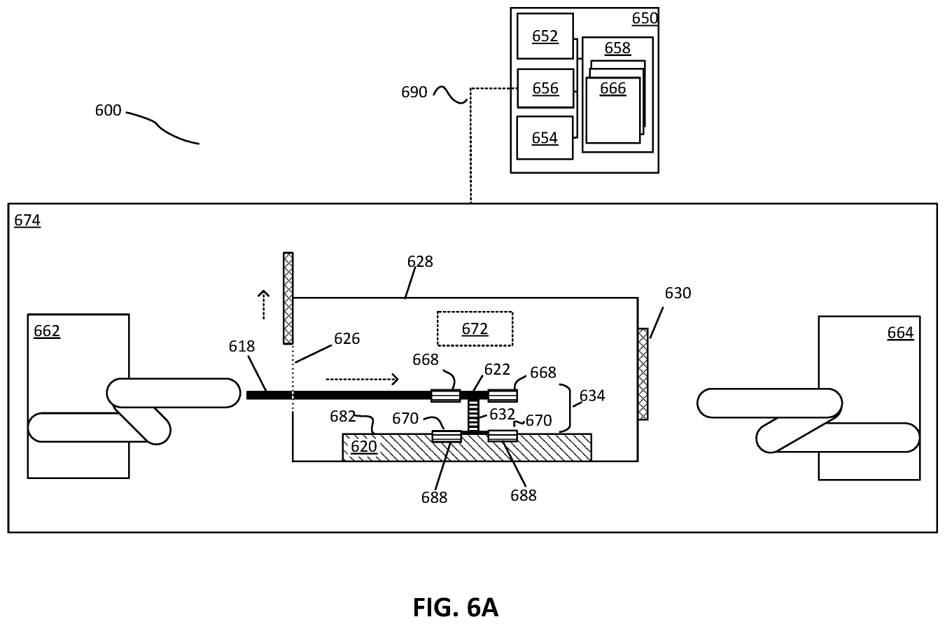

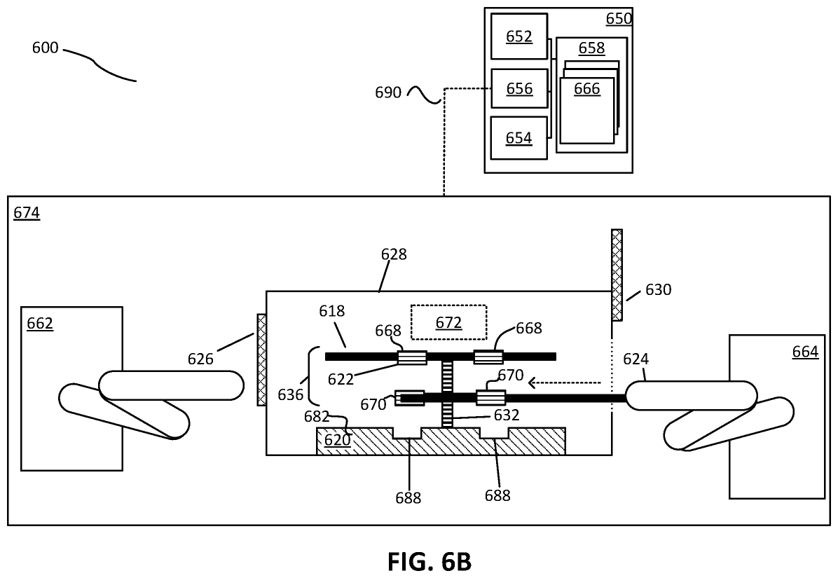

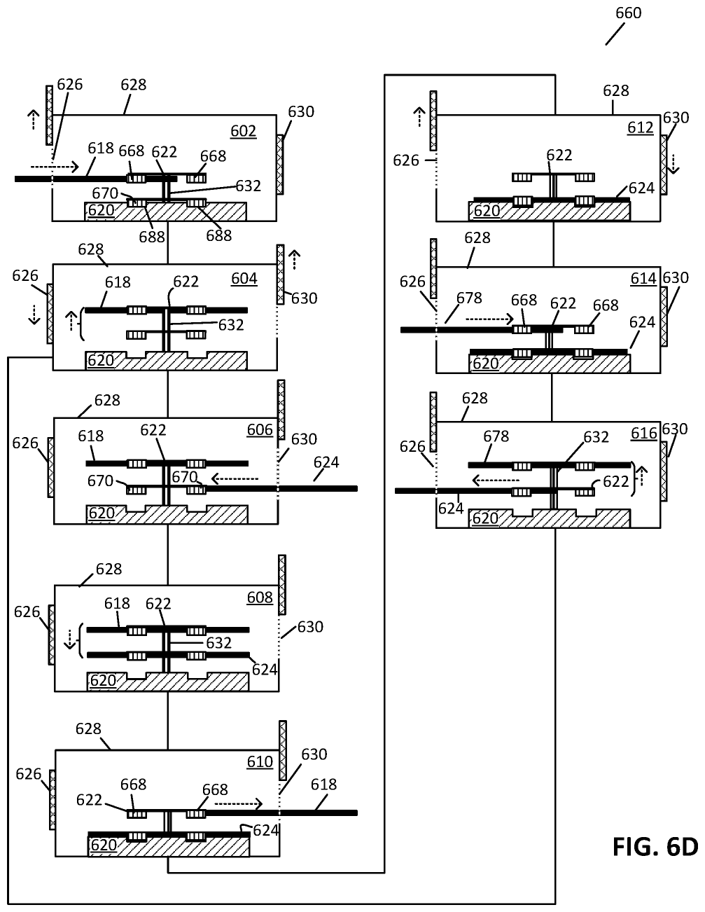

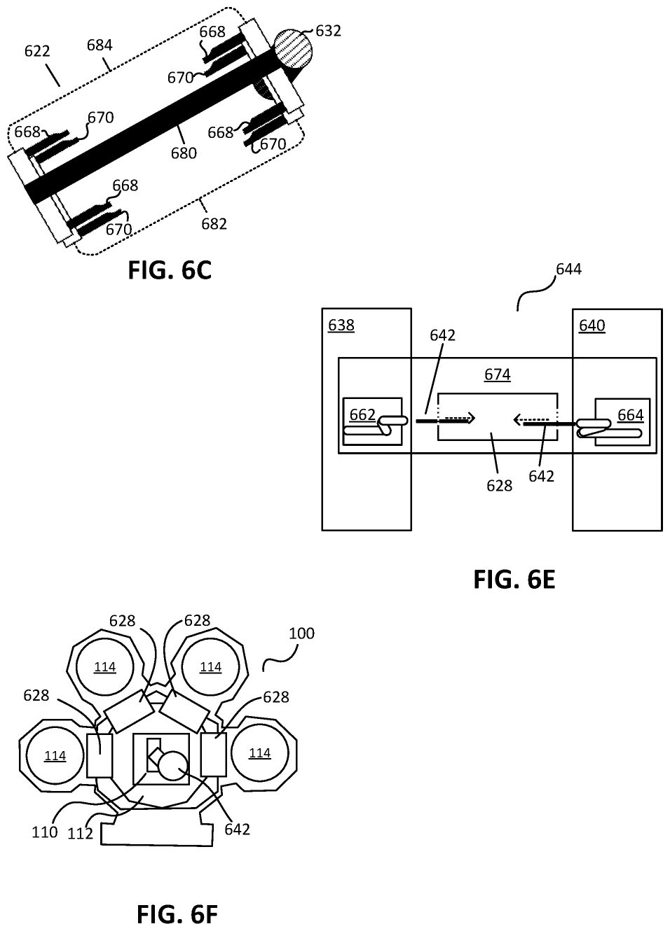

FIG. 6A is a schematic illustrating an example substrate transfer system 600 comprising substrate transfer assembly 674 and controller 650. In an example, controller 650 is coupled to components of substrate transfer assembly 674. In FIG. 6A, indexer 622 is in a lowered first position 634. Controller 650 is configured to control scheduling of substrate transfer process 660 (see FIG. 6D) and corresponding actions executed by substrate transfer assembly 674. Controller 650 may comprise at least one processor 652 having non-transitory memory and including computer code, wherein the at least one processor 652 may be communicatively coupled to devices within substrate transfer assembly 674 configured to execute substrate transfer process 660 (see FIG. 6D). Such devices may include transfer chamber 628, first gate valve 626, second gate valve 630, indexer 622, actuator 632, one or more sensors 672, a first transfer arm 662 and/or second transfer arm 664.

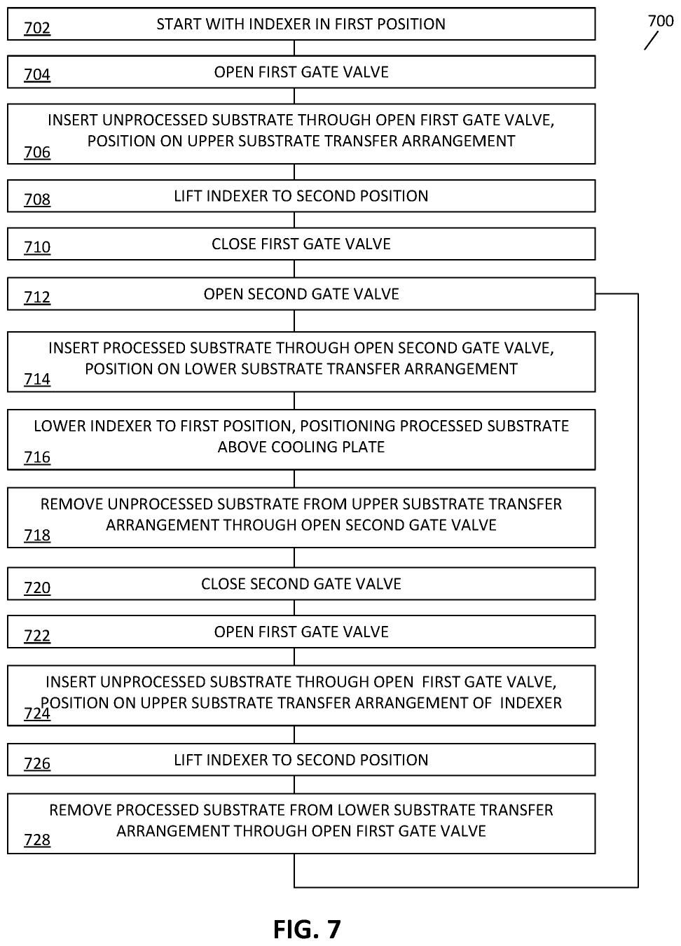

In an example, controller 650 also includes a user interface 654 and a memory 658. The device interface 656 connects the processor 652 to one or more devices or components of substrate transfer assembly 674 to execute one or more predetermined processing actions via the wired or wireless link 690. The processor 652 is operably connected to the user interface 654 (e.g., to receive user input and/or provide user output therethrough) and is disposed in communication with the memory 658. The memory 658 includes a non-transitory machine-readable medium having a plurality of modules 666 recorded thereon containing instructions that, when read by the processor 652, cause the processor 652 to execute certain operations. Among the operations are operations for transferring unprocessed substrate 618 and/or processed substrate 624 as will be described in FIGS. 6C-6D and FIG. 7. As will be appreciated by those of skill in the art in view of the present disclosure, the controller 650 may have a different arrangement in other examples and remain within the scope of the present disclosure.

In an example, the one or more sensors 672 may be configured to detect a variety of conditions within substrate transfer assembly 674 including but not limited to temperature, pressure, light, presence, position of various devices within the substrate transfer assembly 674, or the like or any combinations thereof. The one or more sensors 672 may be configured to generate sensor data and send such data to controller 650 for processing. The sensor data may indicate a status of substrate transfer assembly 674 such as a position of actuator 632 and/or indexer 622, presence or absence of a substrate on a lower-level substrate handling member 670, presence or absence of a substrate on an upper-level substrate handling member 668, whether first gate valve 626 is open, whether second gate valve 630 is open, or the like, or any combinations thereof.

In an example, when indexer 622 is in a lowered first position 634, upper-level substrate handling members 668 may be aligned with first gate valve 626 to enable unprocessed substrate 618 to be passed into transfer chamber 628 by first transfer arm 662 and positioned on upper-level substrate handling member 668. Additionally, lower-level substrate handling members 670 may be disposed within recesses 688 in top surface 686 of cooling plate 620 when indexer 622 is in a lowered first position 634.

FIG. 6B is a schematic illustrating an example substrate transfer system 600 comprising substrate transfer assembly 674 and controller 650. In FIG. 6B indexer 622 is in a raised second position 636. When indexer 622 is raised to second position 636, lower-level substrate handling members 670 may be aligned with second gate valve 630 to enable first transfer arm 664 to pass a processed substrate 624 into transfer chamber 628 and position the processed substrate 624 on lower-level substrate handling members 670. Lower-level substrate handling members 670 may be lifted out of recesses 688 when indexer 622 is moved to raised second position 636 by actuator 632.

FIG. 6C is a schematic, in perspective view, illustrating an example indexer 622. In an example, crossbeam 680 is cantileverly coupled (e.g., cantilevered therefrom) to actuator 632. Lower substrate transfer arrangement 682 comprises a plurality of lower-level substrate handling members 670 coupled to crossbeam 680. Upper-level substrate transfer arrangement 684 comprises a plurality of upper-level substrate handling members 668 coupled to crossbeam 680. Lower-level substrate handling members 670 and upper-level substrate handling members 668 are configured to secure, hold and/or align one or more substrates while being processed, stored or transferred into or out of transfer chamber 628 (see FIG. 6A-6B).

FIG. 6D is a schematic illustrating a high-level abstraction of an example schedule for a substrate transfer process 660 controlled by controller 650. For clarity and simplicity, the description of FIG. 6D below will include reference to features shown in any of FIGS. 6A-6D.

In an example, prior to initializing substrate transfer process 660, controller 650 may run a status check to determine whether substrate transfer assembly 674 is in position to initialize substrate transfer process 660 based on sensor data received from sensor 672. If components of substrate transfer assembly 674 are not in position to initialize substrate transfer process 660, controller 650 may send commands to trigger substrate transfer assembly 674 to take actions to prepare to initialize substrate transfer process 660. For example, controller 650 may send commands to trigger actuator 632 to position indexer 622 in a lowered first position 634 to align upper-level substrate handling member 668 with first gate valve 626 and to position lower-level substrate handling member 670 within recesses 688 of top surface 686 of cooling plate 620. In another example, controller 650 may send commands to trigger opening of first gate valve 626.

In an example, substrate transfer process 660 may begin at block 602, where controller 650 may communicate a command to trigger first transfer arm 662 to insert an unprocessed substrate 618 through open first gate valve 626 of transfer chamber 628 and to position the unprocessed substrate 618 on upper-level substrate handling members 668.

At block 604, controller 650 may communicate a command to trigger actuator 632 to move indexer 622 to a raised second position 636. Also, controller 650 may communicate a command to trigger first gate valve 626 of transfer chamber 628 to close. Controller 650 may communicate a command to trigger second gate valve 630 to open. In some examples, such block 604 commands may be executed in series or simultaneously to improve throughput or for other reasons or may not be performed.

At block 606, controller 650 may communicate a command to trigger second transfer arm 664 to insert a processed substrate 624 through open second gate valve 630 of transfer chamber 628. Second transfer arm 664 may position the processed substrate 624 on lower-level substrate handling member 670.

At block 608, controller 650 may communicate a command to trigger actuator 632 to lower indexer 622 to a lowered first position 634 in order to place processed substrate 624 above cooling plate 620 to cool.

At block 610, controller 650 may communicate a command to trigger second transfer arm 664 to extend through open second gate valve 630 to remove unprocessed substrate 618 from upper-level substrate handling member 668.

At block 612, controller 650 may communicate a command to trigger second gate valve 630 to close. Controller 650 may also communicate a command to trigger first gate valve 626 to open. In some examples, such commands may be executed in series or simultaneously to improve throughput or for other reasons.

At block 614, controller 650 may communicate a command to trigger first transfer arm 662 to extend through open first gate valve 626 to insert a second unprocessed substrate 678 through open first gate valve 626 and position second unprocessed substrate 678 on upper-level substrate handling member 668.

At block 616, controller 650 may communicate a command to trigger actuator 632 to lift indexer 622 to the raised second position 636. Also, controller 650 may communicate a command to trigger first transfer arm 662 to remove processed substrate 624 from lower-level substrate handling member 670 through open first gate valve 626.

In an example, substrate transfer process 660 may proceed by returning to block 604 where new unprocessed substrates (not shown) may enter substrate transfer process 660 and new processed substrates (not shown) may exit substrate transfer process 660.

In various examples, substrate transfer assembly 674 may be disposed (e.g., arranged) in a variety of locations to facilitate substrate transfer throughput in substrate processing assemblies. For example, as illustrated in FIG. 1, substrate transfer assembly 674 may form a part of a load lock assembly 108 between a front-end transfer module 118 and a substrate handling chamber 112. In such example, first transfer arm 662 may be the front-end transfer apparatus 106, transfer chamber 628 may comprise the load lock assembly 108 and second transfer arm 664 may comprise a back-end transfer apparatus 110.

Alternatively, as FIG. 6E illustrates, substrate transfer assembly 674 may form a portion of a passthrough assembly 644 between a first substrate processing assembly 638 and a second substrate processing assembly 640 wherein first transfer arm 662 may comprise a back-end transfer apparatus of first substrate processing assembly 638 and second transfer arm 664 may comprise a back-end transfer apparatus of second substrate processing assembly 640. Transfer chamber 628 may be disposed between first substrate processing assembly 638 and second substrate processing assembly 640 to facilitate transfer of processed or unprocessed substrate 642 from one substrate processing assembly to another.

In another example, transfer chambers 628 may serve as a cooling and/or storage chamber disposed proximate one or more reaction chambers 114, as illustrated in FIG. 6F. Transfer chamber 628 may be disposed between a reaction chamber 114 and substrate handling chamber 112 of substrate processing assembly 100. After processing back-end transfer apparatus 110 may transfer processed substrate 642 to transfer chamber 628 to cool. In some examples, multiple transfer chambers 628 may be disposed between respective reaction chambers 114 and substrate handling chamber 112 to cool multiple substrates after processing in reaction chamber 114. This may improve throughput by cooling multiple substrates simultaneously.

FIG. 7 is a flowchart illustrating an example substrate transfer method 700. For clarity and simplicity, the description of FIG. 7 below will include reference to certain features shown in any of FIGS. 6A-6D.

In an example, substrate transfer method 700 may be executed by any of a variety of substrate processing apparatus, such as components of substrate processing assembly 100 (see FIG. 1) and/or substrate transfer assembly 674. Substrate transfer assembly 674 may include: a transfer chamber 628 opening to a first gate valve 626 and a second gate valve 630, and a cooling plate 620 comprising a top surface 686 having one or more open recesses 688. Substrate transfer assembly 674 may include an indexer 622 radially offset from the cooling plate 620 comprising an actuator 632 assembly configured to translate along a vertical axis to a first position 634 and a second position 636. Crossbeam 680 may extend cantilevered from actuator 632 and may be coupled to lower substrate transfer arrangement 682 comprising a plurality of lower-level substrate transfer members 670 and upper substrate transfer arrangement 684 comprising a plurality of upper-level substrate handling member 668.

In an example, method 700 may begin at operation 702 where indexer 622 may be determined to be in a starting first position 634. If indexer 622 is not in starting first position 634, then actuator 632 may translate indexer 622 to a first position 634. Operation 702 may include coupling a plurality of lower-level substrate handling members 670 into corresponding open recesses 688 of cooling plate 620 to align indexer 622 with cooling plate 620.

At operation 704, first gate valve 626 may be opened via one or more automated processes. Moving to operation 706, unprocessed substrate 618 may be inserted through open first gate valve 626 and positioned on upper-level substrate handling members 668 of upper substrate transfer arrangement 684.

At operation 708, indexer 622 may be moved to second position 636. In an example, actuator 632 may raise indexer 622 in the vertical direction in order to align lower substrate transfer arrangement 682 with second gate valve 630.

At operation 710, first gate valve 626 may be closed via one or more automated processes.

At operation 712, second gate valve 630 may be opened via one or more automated processes. In an example, operations 708, 710, and/or 712 may be performed in series or simultaneously to improve throughput or for other reasons.

At operation 714, processed substrate 624 may be inserted through open second gate valve 630 and may be positioned on lower-level substrate handling members 670 of lower substrate transfer arrangement 682.

At operation 716, indexer 622 may be moved to first position 634. In an example, actuator 632 may vertically translate indexer 622 to first position 634 and lower substrate handling members 670 may be engaged with corresponding open recesses 688 of cooling plate 620 bringing processed substrate 624 into close proximity with the cooling plate to cool processed substrate 624.

At operation 718, unprocessed substrate 618 may be removed from upper substrate transfer arrangement 684 through open second gate valve 630. Second gate valve 630 may be closed at operation 720. First gate valve 626 may be opened at operation 722. In an example, operations 720 and 722 may be performed in series or simultaneously to improve throughput or for other reasons.

At operation 724, second unprocessed substrate 678 may be inserted through open first gate valve 626 and positioned on upper substrate transfer arrangement 684. At operation 726, indexer 622 may be raised to second position 636 by vertical translation of actuator 632. At operation 728, cooled processed substrate 624 may be remove from lower substrate transfer arrangement 682 through open first gate valve 626.

In an example, operations 702 through 728 may be performed sequentially and/or upon completion of operation 728, method 700 may return to operation 710.

Having described and illustrated the general and specific principles of examples of the presently disclosed technology, it should be apparent that the examples may be modified in arrangement and detail without departing from such principles. We claim all modifications and variations coming within the spirit and scope of the following claims.

1. A cooling apparatus comprising:
a cooling plate comprising a top surface including an array of embedded substrate support members protruding therefrom;
a channel disposed in an underside portion of the cooling plate;
a conduit embedded in the channel, the conduit comprising a coolant inlet at a first end and a coolant outlet at a second end;
a viscous thermally conductive material disposed in the channel and thermally coupled to an interior surface of the channel and an exterior surface of the conduit; and
one or more open recesses disposed in a top surface of the cooling plate extending inward from a perimeter of the cooling plate toward a center point of the cooling plate, the open recesses disposed circumferentially on diametrically opposite sides of the cooling plate wherein the open recesses are sized to receive a corresponding substrate handling member of an indexer.

2. The cooling apparatus of claim 1, wherein the array of embedded substrate support members comprise a plurality of standoff spheres each partially embedded in a corresponding cavity in the top surface of the cooling plate wherein the standoff spheres protrude above the top surface of the cooling plate by about 0.3 mm.

3. The cooling apparatus of claim 2, further comprising a vented screw mated into a threaded hole adjacent to one of the plurality of standoff spheres wherein the standoff spheres comprise silicon nitride, quartz or ceramic, or a combination thereof.

4. The cooling apparatus of claim 1, wherein the top surface includes a segmented raised boundary disposed circumferentially about a perimeter of the cooling plate.

5. The cooling apparatus of claim 1, further comprising an array of venting channels patterned into the top surface.

6. A cooling plate arrangement, comprising:
a cooling plate as recited in claim 1 wherein the indexer further comprises:
an actuator assembly configured to translate along a vertical axis to a first position and a second position; and
a crossbeam cantilevered and extending from the actuator assembly along a horizontal axis with respect to the actuator assembly,
wherein the indexer is radially offset from the cooling plate.

7. The cooling plate arrangement of claim 6, further comprising a plurality of substrate handling members coupled to the crossbeam and arranged in pairs at opposing ends of the crossbeam, wherein a first set of opposing pairs of substrate handling members is disposed to circumferentially support a first substrate and a second set of opposing pairs of substrate handling members is disposed to circumferentially support a second substrate, wherein the first set is disposed lower than the second set and wherein corresponding ones of the substrate handling members of the first set are sized to engage with respective ones of the one or more open recesses.

8. The cooling plate arrangement of claim 6, further comprising a pair of spacer block assemblies coupled to an underside of the crossbeam at opposing ends, wherein individuals of the pair of spacer block assemblies further comprise:
at least a first pair of slots and a second pair of slots disposed vertically above the first pair of slots; and
a first pair of substrate handling members each having a first mating end engaged within respective ones of the first pair of slots and a second pair of substrate handling members each having a second mating end engaged within respective ones of the second pair of slots.

9. The cooling plate arrangement of claim 8, wherein individual ones of the plurality of substrate handling members comprise a transport end having an end face directed toward a transverse plane through a center of the crossbeam, the end face comprising a recessed edge including an angled sidewall that is spaced apart from the end face.

10. The cooling plate arrangement of claim 9, wherein the angled sidewall or the end face, or a combination thereof, are disposed at an acute interior angle or an obtuse interior angle with respect to a centerline parallel to a lengthwise axis of the substrate handling member.

11. A substrate transfer system, comprising:
the cooling plate arrangement as recited in claim 7;
a substrate transfer chamber including a housing to enclose the cooling plate and the indexer, wherein the indexer comprises a lower substrate transfer arrangement including the first opposing pair and an upper substrate transfer arrangement including the second opposing pair; and
a controller disposed in communication with and operatively connected to the indexer, the controller responsive to instructions recorded on a non-transitory machine-readable memory to lower the indexer to the first position to mate the first opposing vertical pair within the open recesses or to raise the indexer to the second position removing the first opposing pair from within the open recesses, or a combination thereof.

12. The substrate transfer system of claim 11, wherein the controller is further in communication and operatively connected with a first gate valve coupled to the housing and a second gate valve coupled to the housing and wherein the instructions further cause the controller to simultaneously close the first gate valve and raise the indexer to the second position.

13. The substrate transfer system of claim 12, wherein the instructions further cause the controller to simultaneously open the first gate valve and close the second gate valve.

14. The substrate transfer system of claim 11, wherein the controller is further in communication and operatively connected with a first gate valve coupled to the housing, a second gate valve coupled to the housing, a first transfer arm disposed adjacent to the first gate valve and a second transfer arm disposed adjacent to the second gate valve and wherein the instructions further cause the controller to:
a) move the indexer to the first position;
b) open the first gate valve;
c) extend the first transfer arm to insert an unprocessed substrate through the open first gate valve and position the unprocessed substrate on an upper substrate transfer arrangement;
d) move the indexer to a second position;
e) close the first gate valve;
f) open the second gate valve;
g) extend the second transfer arm to insert a processed substrate through the open second gate valve and position the processed substrate on the lower substrate transfer arrangement;
h) move the indexer to the first position;
i) extend the second transfer arm through the open second gate valve to remove the unprocessed substrate from the upper substrate transfer arrangement;
j) close the second gate valve;
k) open first gate valve;
l) extend the first substrate transfer arm through the open first gate valve to insert a second unprocessed substrate through the open first gate valve and position the second unprocessed substrate on the upper substrate transfer arrangement;
m) move indexer to the second position; and
n) remove the processed substrate from the lower substrate transfer arrangement through open first gate valve.

15. The substrate transfer system of claim 14, wherein the instructions further cause the controller to perform actions a-n sequentially.

16. The substrate transfer system of claim 14, wherein the instructions further cause the controller to proceed from action e upon completing action n.

17. The substrate transfer system of claim 14, wherein the instructions further cause the controller to perform actions d-e-f or j-k simultaneously, or a combination thereof.

18. A substrate transfer method, comprising:
at a chamber arrangement including a transfer chamber opening to a first gate valve and a second gate valve; a cooling plate comprising a top surface having one or more open recesses extending inward from a perimeter of the cooling plate toward a center point of the cooling plate; an indexer radially offset from the cooling plate comprising an actuator assembly configured to translate along a vertical axis to a first position and a second position; and a crossbeam cantilevered and extending from the actuator assembly along a horizontal axis with respect to the actuator assembly; a plurality of substrate handling members coupled to the crossbeam;
a) moving the indexer to a first position and coupling the plurality of substrate handling members into corresponding open recesses;
b) opening the first gate valve;
c) inserting an unprocessed substrate through the open first gate valve and positioning the unprocessed substrate on an upper substrate transfer arrangement;
d) moving the indexer to a second position;
e) closing the first gate valve;
f) opening the second gate valve;
g) inserting a processed substrate through the open second gate valve and positioning the processed substrate on the lower substrate transfer arrangement;
h) moving the indexer to the first position and coupling the one or more substrate handling members into the corresponding open recesses to cool the processed substrate;
i) removing the unprocessed substrate from the upper substrate transfer arrangement through the open second gate valve;
j) closing the second gate valve;
k) opening first gate valve;
l) inserting a second unprocessed substrate through the open first gate valve and positioning the second unprocessed substrate on the upper substrate transfer arrangement;
m) moving indexer to the second position; and
n) removing the cooled processed substrate from the lower substrate transfer arrangement through open first gate valve.

19. The substrate transfer method of claim 18, further comprising performing actions a-n sequentially.

20. The substrate transfer method of claim 18, further comprising proceeding to action e upon completing action n.
